(19) United States
(12) Patent Application Publication
(10) Pub. No.: US 2010/0117157 A1
(43) Pub. Date: May 13, 2010

(54) SEMICONDUCTOR DEVICE

(75) Inventor: Shinichi MIYAKE, Kanagawa (JP)

Correspondence Address: YOUNG & THOMPSON, 209 Madison Street, Suite 500, Alexandria, VA, 22314, US

(73) Assignee: NEC CORPORATION, Kawasaki-shi (JP)

(21) Appl. No.: 12/617,441

(22) Filed: Nov. 12, 2009

(30) Foreign Application Priority Data
Nov. 11, 2008 (JP) 2008-289187

(51) Int. Cl. H01L 29/78

(52) U.S. Cl. 257/368; 257/E29.255

(57) ABSTRACT

A semiconductor device includes: an element isolation layer provided in a semiconductor layer; an element region divided by the element isolation layer; a gate interconnect which extends over the element region and the element isolation layer; a sidewall formed at a sidewall of the gate interconnect; and a contact connected to the gate interconnect located over the element isolation layer. The sidewall of the gate interconnect has a region, which is in contact with the contact, in at least an upper portion.

The application is based on Japanese patent application No. 2008-289187, the content of which is incorporated hereinto by reference.

### BACKGROUND

1. Technical Field

The present invention relates to a semiconductor device which is small and in which an influence of a positional deviation between a gate interconnect and a contact on the characteristics of a circuit is reduced.

2. Related Art

FIG. 22 is a plan view explaining the configuration of a known semiconductor device. In this semiconductor device, a transistor is formed in an element region. The transistor has two diffusion layers 520, which become a source and a drain, and a gate interconnect 540. The element region is divided by an element isolation layer, and the gate interconnect 540 extends over the element region and the element isolation layer. A contact 570 is connected to each of the two diffusion layers 520, and a contact 560 is connected to the gate interconnect 540. The contact 560 is connected to the gate interconnect 540 over the element isolation layer.

As the size of a semiconductor device has decreased in recent years, the width of the gate interconnect 540 is becoming smaller than the diameter of the contact 560. In this case, if the positional deviation occurs in the contacts 560 and 570, the contact area between the contact 570 and the gate interconnect 540 is reduced and the contact resistance increases accordingly. In order to suppress this, it is necessary to make wide a contact region 544 of the gate interconnect 540 where the contact 560 is connected, compared with other portions.

In this case, however, the periphery 542 of the contact region 544 also becomes gradually wide in the form dragged to the contact region 544. When the periphery 542 is positioned over the diffusion layer 520, the characteristics of a circuit including the transistor are changed. In order to prevent this, it is necessary to ensure the distance between the transistor and the contact region 544 to be equal to or larger than a predetermined value. An example of such a technique is disclosed in Japanese Unexamined patent publication NO. 2007-208058.

In addition, Domestic Re-publication of PCT International Application JP A1, 2003/098698 discloses the following method of manufacturing a semiconductor device. First, a gate insulating layer is formed over a predetermined region of a semiconductor substrate, and a gate electrode is formed over the gate insulating layer. Then, a source region and a drain region are formed in portions of the predetermined region which are located at both sides of the gate electrode when seen in a plan view, respectively, and a contact which electrically connects the gate electrode with a body region, which is a region excluding the source and drain regions of the predetermined region, is formed. Here, a portion of the contact connected to the gate electrode is formed so as to cross the gate electrode when seen in a plan view.

As described above, when the contact region of the gate interconnect where the contact is connected is made wider than other portions, the periphery of the contact region also becomes gradually wider. For this reason, it is necessary to ensure the distance between the transistor and the contact region to be equal to or more than the predetermined value. Therefore, in order to make a semiconductor device small, it is preferable not to make the contact region wide so that the influence of the positional deviation of a contact on the circuit characteristics is reduced.

### SUMMARY

In one embodiment, there is provided a semiconductor device including: a substrate; an element isolation layer provided on said substrate; an element region divided by said element isolation layer; a gate interconnect including a sidewall and extending over said element region and said element isolation layer; an insulating layer on said substrate; and a contact connected to said gate interconnect with an upper and a side surface of said gate interconnect located over said element isolation layer through said insulating layer. A film thickness of said sidewall on said element isolation layer on said substrate is substantially equal to a film thickness of said sidewall on said element region.

According to the embodiment of the present invention, when the diameter of the contact (plug) is larger than the width of the gate interconnect, the contact (plug) is in contact with the upper surface of the gate interconnect and at least the upper portion of the sidewall. Accordingly, the connection resistance between the contact (plug) and the gate interconnect can be reduced. In addition, when the diameter of the contact (plug) is equal to or less than the width of the gate interconnect, even if the positional deviation of the contact occurs, an increase in connection resistance between the contact (plug) and the gate interconnect can be suppressed because the region of at least the upper portion of the sidewall of the gate interconnect is in contact with the contact. Accordingly, it is not necessary to make thick a region of the gate interconnect in contact with the contact (plug), and it is suppressed that the connection resistance becomes larger than the reference value even if the positional deviation of the contact occurs. As a result, an influence of the positional deviation of the contact on the circuit characteristics can be reduced while making the semiconductor device small.

According to the embodiment of the present invention, it is not necessary to make thick a region of the gate interconnect in contact with the contact (plug), and it is suppressed that the connection resistance becomes larger than the reference value even if the positional deviation of the contact occurs. As a result, an influence of the positional deviation of the contact on the circuit characteristics can be reduced while making the semiconductor device small.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B are sectional views showing a semiconductor device according to a first embodiment;

FIG. 2 is a plan view showing the semiconductor device shown in FIGS. 1A and 1B;

FIGS. 3A and 3B are sectional views explaining a method of manufacturing a semiconductor device;

FIGS. 4A and 4B are sectional views explaining a method of manufacturing a semiconductor device;

FIGS. 5A and 5B are sectional views explaining a method of manufacturing a semiconductor device;

FIGS. 6A and 6B are sectional views showing the configuration of a semiconductor device according to a second embodiment;

FIGS. 7A and 7B are sectional views explaining a method of manufacturing the semiconductor device shown in FIGS. 6A and 6B;

FIGS. 8A and 8B are sectional views showing the configuration of a semiconductor device according to a third embodiment;

FIGS. 9A and 9B are sectional views showing the configuration of a semiconductor device according to a fourth embodiment;

FIGS. 10A and 10B are sectional views explaining a method of manufacturing the semiconductor device shown in FIGS. 9A and 9B;

FIG. 11 is a sectional view showing a semiconductor device according to a fifth embodiment;

FIG. 12 is a sectional view showing a semiconductor device according to a sixth embodiment;

FIG. 13 is a sectional view showing a semiconductor device according to a seventh embodiment;

FIG. 14 is a sectional view showing a semiconductor device according to an eighth embodiment;

FIGS. 15A and 15B are sectional views showing a method of manufacturing the semiconductor device shown in FIG. 14;

FIGS. 16A and 168 are sectional views showing a method of manufacturing the semiconductor device shown in FIG. 14;

FIG. 17 is a plan view showing a semiconductor device according to a ninth embodiment;

FIG. 18 is a plan view showing a semiconductor device according to a tenth embodiment;

FIG. 19 is a plan view showing a semiconductor device according to an eleventh embodiment;

FIGS. 20A and 20B are plan views showing main parts of a semiconductor device according to a twelfth embodiment;

FIG. 21 is a plan view showing a semiconductor device according to a thirteenth embodiment;

FIG. 22 is a plan view explaining the configuration of a known semiconductor device;

FIG. 23 is the process flow of the first embodiment; and

FIG. 24 is the process flow of the fourth embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

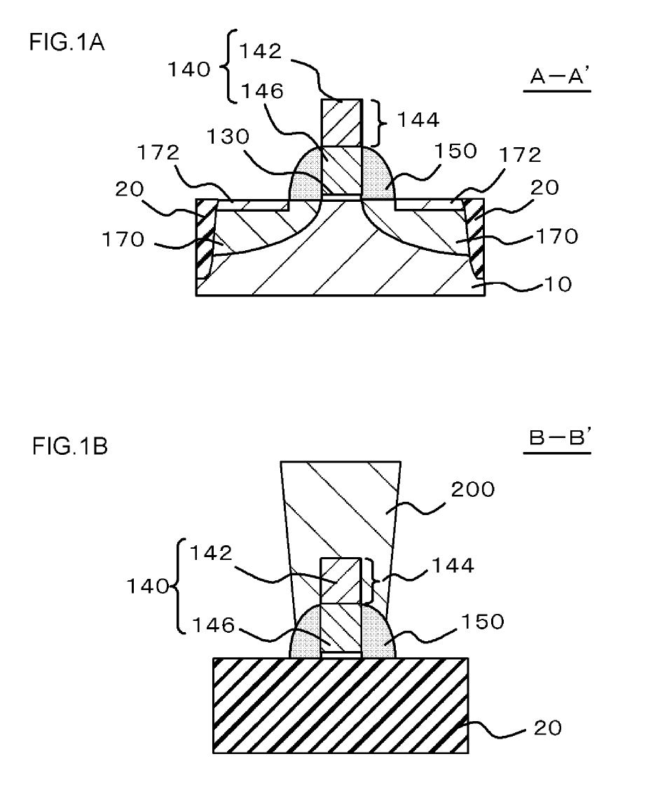

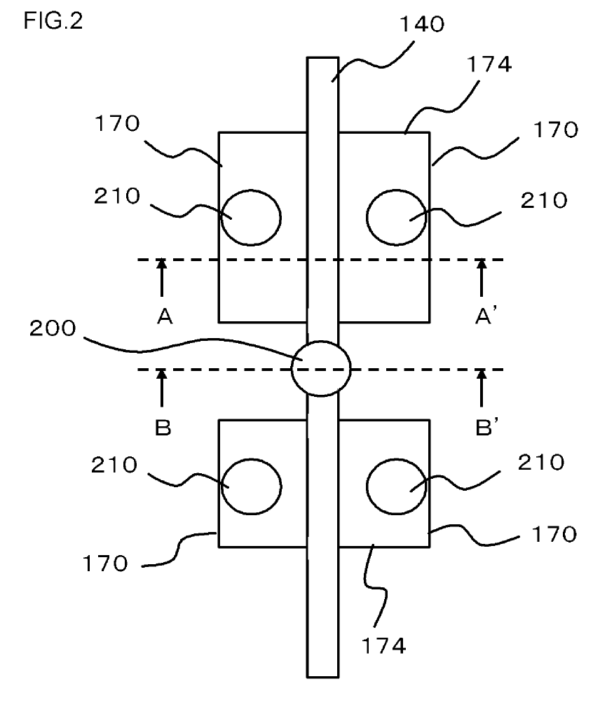

Hereinafter, embodiments will be described with reference to the accompanying drawings. In addition, the same components are denoted by the same reference numerals in all drawings, and the explanation will not be repeated. FIGS. 1A and 1B are sectional views showing the configuration of a semiconductor device according to a first embodiment, and FIG. 2 is a plan view showing the semiconductor device shown in FIGS. 1A and 1B. FIG. 1A is a sectional view taken along the line A-A′ of FIG. 2, and FIG. 1B is a sectional view taken along the line B-B′ of FIG. 2.

This semiconductor device includes an element region 174, an element isolation layer 20, a gate interconnect 140, a sidewall 150, and a contact (plug) 200. The element isolation layer 20 is provided in a semiconductor layer 10. The element region 174 is divided by the element isolation layer 20. The gate interconnect 140 extends over the element region 174 and the element isolation layer 20. The sidewall 150 is formed at a sidewall of the gate interconnect 140. The contact (plug) 200 is connected to a portion of the gate interconnect 140 located over the element isolation layer 20. In addition, the gate interconnect 140 has a region 144, which is not covered by the sidewall 150, at an upper portion of a side surface (sidewall) of a portion connected to the contact (plug) 200. Moreover, in the region 144, the gate interconnect 140 is in contact with the contact (plug) 200.

Accordingly, as shown in the drawings, when the diameter of the contact (plug) 200 is larger than the width of the gate interconnect 140 in a horizontal plane including an upper surface of the gate interconnect 140, the contact (plug) 200 is in contact with the upper surface and region 144 of the gate interconnect 140. In this case, since the contact area between the contact (plug) 200 and the gate interconnect 140 becomes large, the connection resistance between the contact (plug) 200 and the gate interconnect 140 can be reduced. Accordingly, even if positional deviation of the contact (plug) 200 occurs, it is suppressed that the connection resistance becomes larger than the reference value. As a result, the influence of the positional deviation of the contact (plug) 200 on the circuit characteristics can be reduced.

In addition, even if the diameter of the contact (plug) 200 is equal to or less than the width of the gate interconnect 140, the region 144 of the gate interconnect 140 and the contact (plug) 200 are in contact with each other when the contact (plug) 200 protrudes from the gate interconnect 140 due to the positional deviation. In this case, an increase in the connection resistance between the contact (plug) 200 and the gate interconnect 140 can be suppressed. Accordingly, even if positional deviation of the contact (plug) 200 occurs, it is suppressed that the connection resistance becomes larger than the reference value. As a result, an influence of the positional deviation of the contact (plug) 200 on the circuit characteristics can be reduced.

For this reason, the gate interconnect 140 may be formed in a straight line so that the width of a portion of the gate interconnect 140 connected to the contact (plug) 200 becomes equal to the width of a portion of the gate interconnect 140 located over the element region 174. Accordingly, the gap between the adjacent element regions 174 can be narrowed. As a result, the degree of integration of the device can be improved.

The height of the region 144 is preferably equal to or more than ⅕ of the height of the gate interconnect 140. In addition, the height of the region 144 is preferably 10 nm or more. More preferably, the height of the region 144 is 20 nm or more. In addition, the height of the sidewall 150 is equal in all portions of the gate interconnect 140. Specifically, the height of the sidewall 150 in a portion where the gate interconnect 140 is connected to the contact (plug) 200 is equal to the height of the sidewall 150 located over the element region 174.

The gate interconnect 140 includes a polysilicon layer 146 and a silicide layer 142 provided over the polysilicon layer 146. The silicide layer 142 is not covered by the sidewall 150 in the region 144 of a part of the side surface of the gate interconnect 140 and the upper surface of the gate interconnect 140, and is connected to (in contact with) the contact (plug) 200 in each of the portions. In this way, the connection resistance between the contact (plug) 200 and the gate interconnect 140 can be reduced further. Although it is preferable that the entire side surface of the silicide layer 142 is the region 144, a part of the side surface of the silicide layer 142 may be the region 144.

In addition, two impurity diffusion layers 170 which become a source and a drain of a transistor are formed in the semiconductor layer 10 located in the element region 174. The two impurity diffusion layers 170 are located opposite each other with a region forming a channel of the semiconductor layer 10, which is located below the gate interconnect 140, interposed therebetween. A silicide layer 172 is formed at a surface layer of the impurity diffusion layer 170. The impurity diffusion layer 170 is connected to a contact (plug) 210 through the silicide layer 172. The sectional shapes of the contacts (plugs) 200 and 210 are approximately circular.

In addition, a gate insulating layer 130 is formed below the gate interconnect 140. The gate insulating layer 130 may be a high dielectric constant layer formed of a material with a higher relative dielectric constant than silicon oxide, may be a silicon oxide layer, or may be a laminated structure in which a high dielectric constant layer is formed over a silicon oxide layer. For example, the high dielectric constant layer is a silicate layer, such as an HfSiON layer or a ZrSiON layer, which contains N (nitrogen) and one or two or more elements selected from the group consisting of Hf, Zr, and lanthanoids.

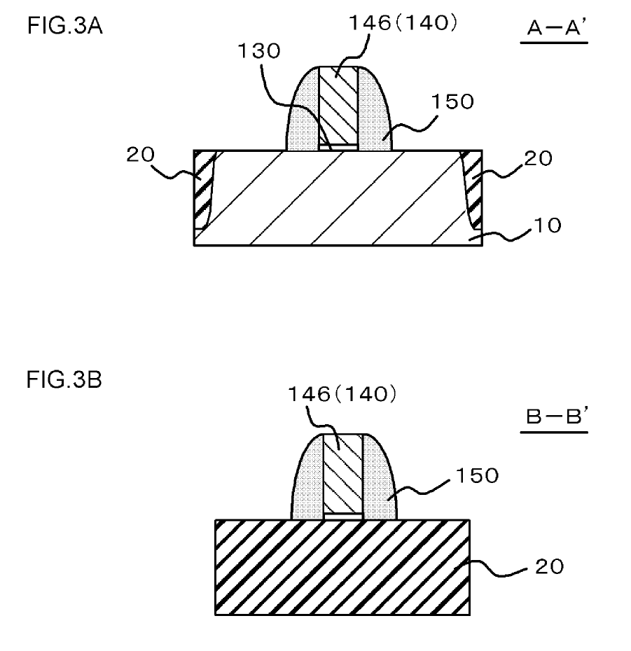

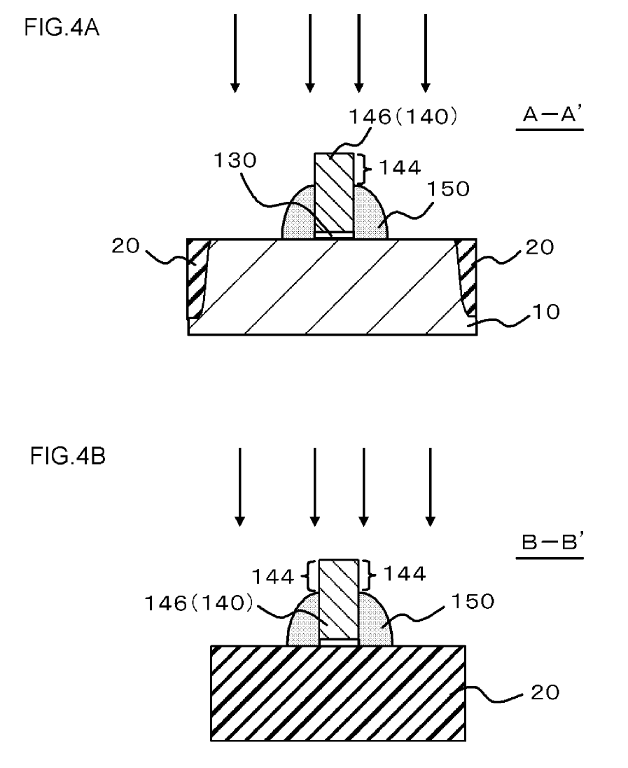

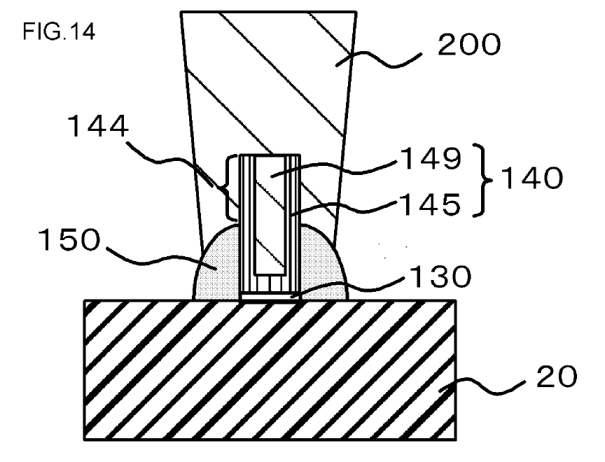

Next, a method of manufacturing the semiconductor device shown in FIGS. 1A, 1B, and 2 will be described using FIGS. 3A to 5B and the sectional views of FIGS. 1A and 13. The process flow of the present embodiment is shown in FIG. 23. FIGS. 3A, 4A, and 5A correspond to the sectional view taken along the line A-A′ of FIG. 2, and FIGS. 3B, 4B, and 5B correspond to the sectional view taken along the line B-B′ of FIG. 2.

First, as shown in FIGS. 3A and 3B, the element isolation layer 20 is formed in the semiconductor layer 10. The semiconductor layer 10 may be a semiconductor substrate or may be a semiconductor layer of an SOI substrate. The element isolation layer 20 has a shallow trench structure, for example.

Then, the gate insulating layer 130 and the gate interconnect 140 are formed over the semiconductor layer 10, and then the sidewall 150 is formed. In this state, the silicide layer 142 is not formed in the gate interconnect 140. After forming the gate interconnect 140, the extension regions of the source and drain are formed using an ion implantation method before forming the sidewall 150.

Then, the entire surface for exposing the sidewall 150 is etched back as shown in FIGS. 4A and 4B. As a result, the sidewall 150 becomes small, and the region 144 which is not covered by the sidewall 150 is formed in an upper portion of each of the two side surfaces of the gate interconnect 140. This etchback process may be performed simultaneously with an etchback process for forming the sidewall. In addition, the etchback is performed by dry etching. However, for example, the etchback may be performed by wet etching. In the present embodiment, the film thickness of the sidewall 150 formed in the element region 174 is approximately equal to the film thickness of the sidewall 150 formed over the element isolation layer 20.

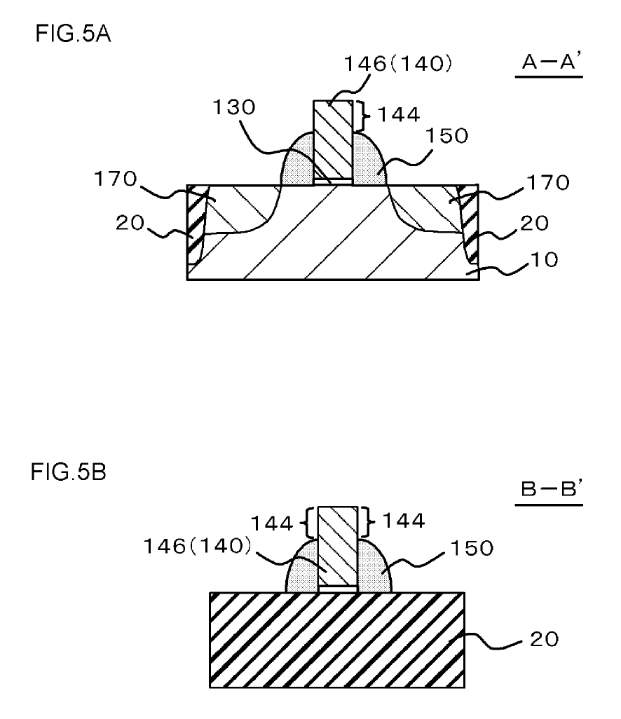

Then, as shown in FIGS. 5A and 5B, the impurity diffusion layer 170 is formed using the ion implantation method, for example, so as to be self-aligned.

Then, as shown in FIGS. 1A and 1B, a region where silicide is not to be formed among a region where silicon is exposed is covered by a silicide block layer (not shown in the drawings), and then a metal layer using Ni, Co, or the like is formed by the gas phase method and is heat-treated. As a result, the silicide layers 142 and 172 using nickel silicide or cobalt silicide, for example, are formed. Then, the metal layer which is not a silicide and the silicide block layer are removed.

Then, an interlayer insulating layer (not shown in the drawings) and a connection hole are formed, and a conductive layer (for example, a tungsten layer) is embedded in the connection hole. As a result, the contacts (plugs) 200 and 210 are formed.

As described above, according to the first embodiment, the gate interconnect 140 has the region 144, which is not covered by the sidewall 150, at the upper portion of the side surface of the portion connected to the contact (plug) 200. Accordingly, when the diameter of the contact (plug) 200 is larger than the width of the gate interconnect 140 in the horizontal plane including the upper surface of the gate interconnect 140, the contact area between the contact (plug) 200 and the gate interconnect 140 becomes large. As a result, the connection resistance between the contact (plug) 200 and the gate interconnect 140 can be reduced. Thus, the influence of the positional deviation of the contact (plug) 200 on the circuit characteristics can be reduced.

For this reason, the gate interconnect 140 may be formed in a straight line so that the width of a portion of the gate interconnect 140 connected to the contact (plug) becomes approximately equal to the width of a portion of the gate interconnect 140 located over the element region 174. As a result, the gap between the adjacent element regions 174 can be narrowed. In this way, the semiconductor device can be made small.

In addition, the silicide layer 142 of the gate interconnect 140 is in contact with the contact (plug) 200 in at least a part of the region 144 of the side surface of the gate interconnect 140 and the upper surface of the gate interconnect 140. Accordingly, the connection resistance between the contact (plug) 200 and the gate interconnect 140 can be reduced further.

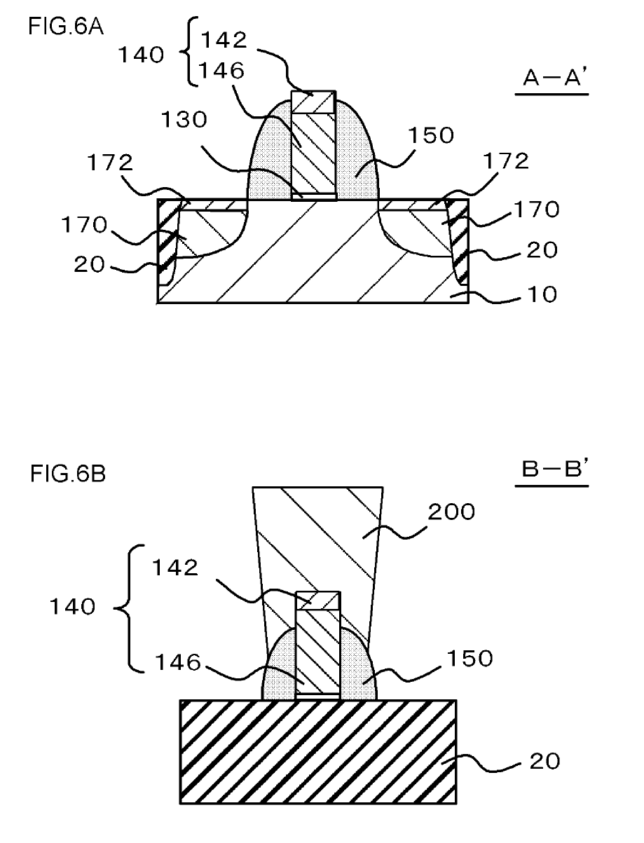

FIGS. 6A and 6B are sectional views showing a semiconductor device according to a second embodiment. FIGS. 6A and 6B correspond to FIGS. 1A and 1B in the first embodiment. FIG. 6A corresponds to the sectional view taken along the line A-A′ of FIG. 2 in the first embodiment, and FIG. 6B corresponds to the sectional view taken along the line B-B′ of FIG. 2 in the first embodiment. This semiconductor device is the same as that according to the first embodiment except that the sidewall 150 located in the element region 174 is higher than the sidewall 150 in a region where the gate interconnect 140 and the contact (plug) 200 are connected to each other and covers approximately the entire side surface of the gate interconnect 140. That is, the region 144 is not formed in the gate interconnect 140 located in the element region.

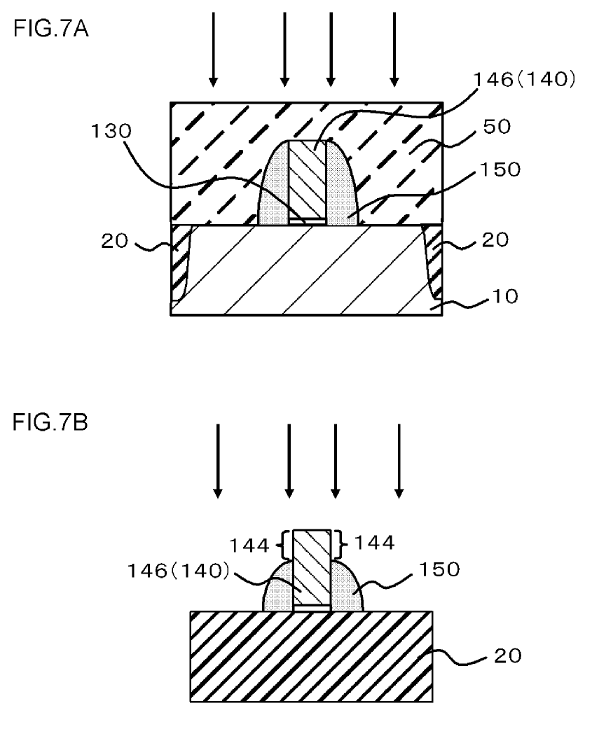

FIGS. 7A and 7B are sectional views explaining the method of manufacturing the semiconductor device shown in FIGS. 6A and 6B. FIG. 7A corresponds to the sectional view taken along the line A-A′ of FIG. 2, and FIG. 7B corresponds to a sectional view taken along the line B-B′ of FIG. 2. A method of manufacturing the semiconductor device is the same as the method described using FIGS. 1A and 1B and 3A to 5B in the first embodiment except that the sidewall 150 and the gate interconnect 140 located in the element region 174 are covered by a mask layer 50, such as a resist, in the process of forming the region 144 by forming the sidewall 150 low. The explanation will not be repeated.

Also in the second embodiment, the same effects as in the first embodiment can be achieved. In addition, the sidewall 150 located in the element region is higher than the sidewall 150 in the region where the gate interconnect 140 and the contact (plug) 200 are connected to each other and has approximately the same shape as the case where the region 144 is not formed. Accordingly, even if the manufacturing conditions are not changed, the characteristics of a transistor can be made to be approximately equal to those in the case where the region 144 is not formed.

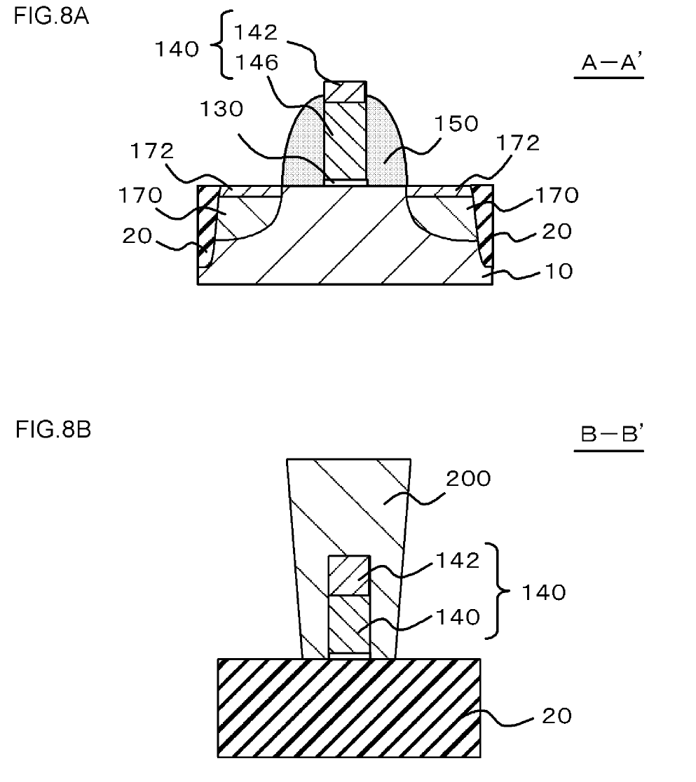

FIGS. 8A and 8B are sectional views showing a semiconductor device according to a third embodiment. FIGS. 8A and 8B correspond to FIGS. 6A and 6B in the second embodiment. Specifically, FIG. 8A corresponds to the sectional view taken along the line A-A′ of FIG. 2 in the first embodiment, and FIG. 8B corresponds to the sectional view taken along the line B-B′ of FIG. 2 in the first embodiment. This semiconductor device is the same as that according to the second embodiment except that the sidewall 150 is removed in the region where the gate interconnect 140 and the contact (plug) 200 are connected to each other. In addition, a method of manufacturing the semiconductor device according to the third embodiment is approximately the same as the method of manufacturing the semiconductor device according to the second embodiment.

Also in the third embodiment, the same effects as in the second embodiment can be achieved. Moreover, since approximately the entire side surface of the gate interconnect 140 is in contact with the contact (plug), the connection resistance between the contact (plug) 200 and the gate interconnect 140 can be reduced further.

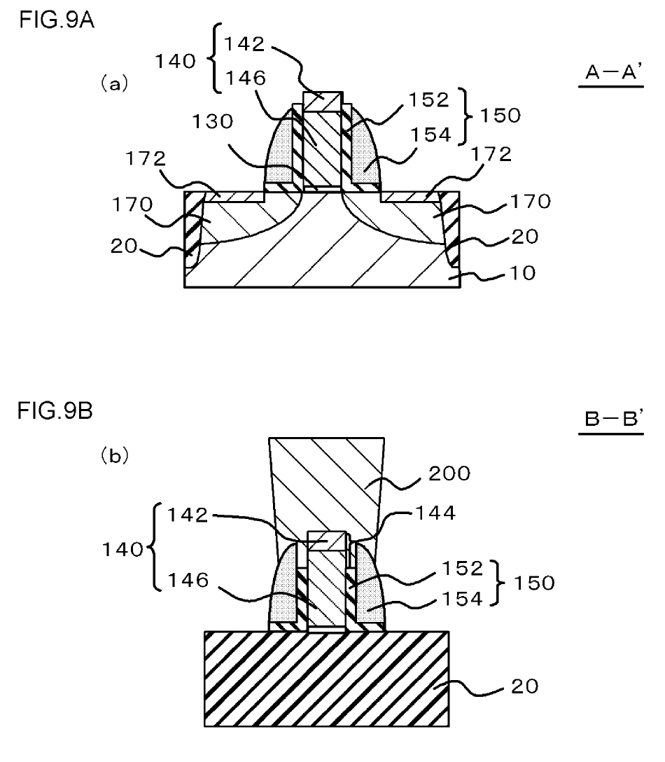

FIGS. 9A and 9B are sectional views showing a semiconductor device according to a fourth embodiment. FIGS. 9A and 9B correspond to FIGS. 1A and 1B in the first embodiment. Specifically, FIG. 9A corresponds to the sectional view taken along the line A-A′ of FIG. 2, and FIG. 9B corresponds to the sectional view taken along the line B-B′ of FIG. 2. This semiconductor device has the same configuration as that in the first embodiment except that the sidewall 150 is formed by a sidewall body 154 and a base layer 152, the region 144 is formed by removing an upper portion of the base layer 152 without removing the sidewall body 154 and a notch shape, in which the contact (plug) 200 goes through the space where the base layer 152 is removed, is formed. The base layer 152 is located between the sidewall body 154 and the gate interconnect 140 and between the sidewall body 154 and the semiconductor layer 10 or the element isolation layer 20. The thickness of the base layer 152 is equal to or more than 5 nm and equal to or less than 20 nm, for example.

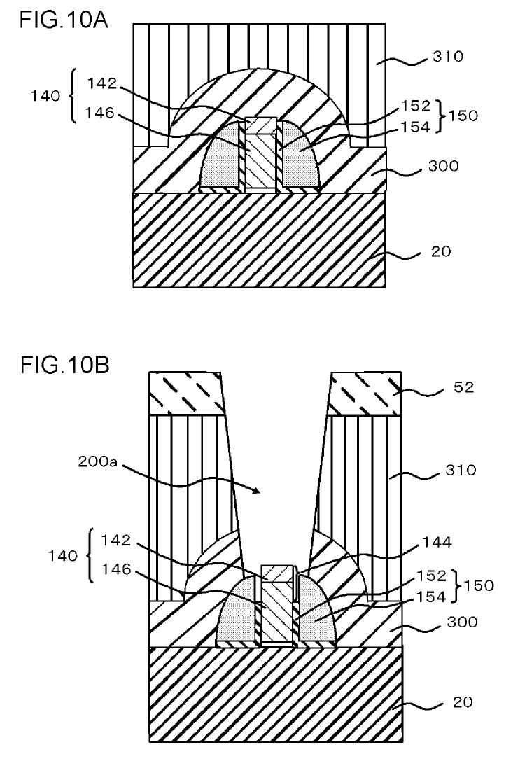

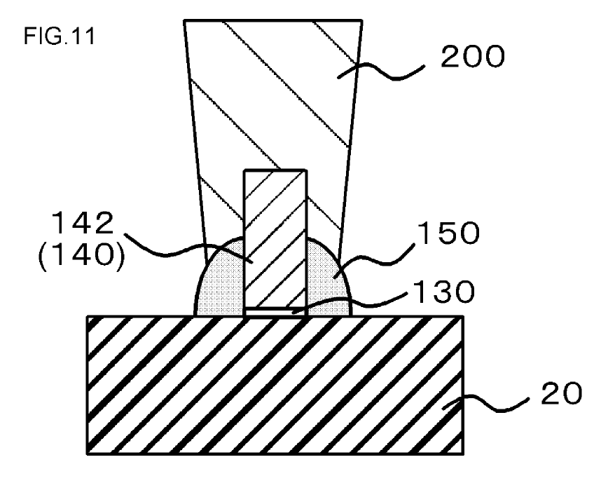

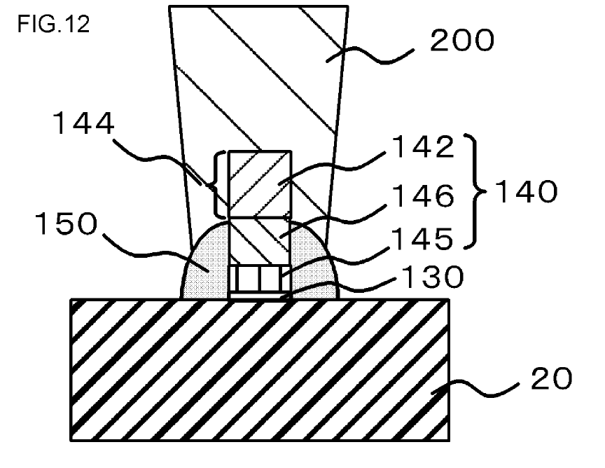

FIGS. 10A and 10B are sectional views explaining a method of manufacturing the semiconductor device shown in FIGS. 9A and 9B. FIGS. 10A and 10B correspond to the sectional view taken along the line B-B′ of FIG. 2 in the first embodiment. The process flow of the present embodiment is shown in FIG. 24. The gate interconnect 140 is formed, and the extension regions of the source and drain are formed by ion implantation as necessary. After forming the sidewall 150 formed by the base layer 152 and the sidewall body 154, a process of performing etching of the sidewall 150 for gate sidewall exposure of a contact region is not performed. Then, the source and drain impurity diffusion layers 170 are formed by the ion implantation method and annealing. After forming a silicide block layer similar to the first embodiment, a metal layer for formation of silicide is formed and heat treatment or the like is performed to thereby form the silicide layers 142 and 172 over the source and drain impurity diffusion layers 170. Then, the metal layer which is not silicided and the silicide block layer are removed.

Then, a stopper layer 300 and an interlayer insulating layer 310 are formed in this order over a transistor of the element region, the gate interconnect 140, and the element isolation layer 20. The stopper layer 300 is formed of a material whose etching selectivity is higher than that of the interlayer insulating layer 310 and is lower than that of the base layer 152. For example, when the base layer 152 is formed of SiN and the interlayer insulating layer 310 is formed of SiO2, SiN which is the same material as the base layer 152 may be used for the stopper layer 300.

Subsequently, as shown in FIG. 10B, a mask pattern 52 is formed and then etching is performed using the stopper layer 300 as a stopper. As a result, a connection hole 200a is formed in the interlayer insulating layer 310. Then, the stopper layer 300 is etched. As a result, the connection hole 200a passes through the stopper layer 300. In etching of the stopper layer 300, an upper portion of the base layer 152 is removed such that the notch shape is formed. As a result, the region 144 is formed.

Then, the mask pattern 52 is removed. Subsequently, a conductive layer is embedded in the connection hole 200a.

As a result, the contact (plug) 200 is formed. Moreover, in the above process, the contact (plug) 210 shown in FIG. 2 in the first embodiment is also formed. In the present embodiment, the film thickness of the sidewall 150 formed in the element region 174 is approximately equal to the film thickness of the sidewall 150 formed over the element isolation layer 20.

Also in the fourth embodiment, the same effects as in the first embodiment can be achieved since the contact (plug) 200 goes through the space where the base layer 152 is removed. Here, in Japanese Unexamined Patent Publication NO. 2007-208058, a sidewall of a necessary place is removed using a mask after forming source and drain impurity diffusion layers. In this case, if this process is removed, the sidewall on the source and drain impurity diffusion layers 170 recedes. Then, since the bonding boundary position of the source and drain impurity diffusion layers 170 and the position of the silicide are brought close to each other, P/N bonding leakage occurs in this portion. In the present embodiment, the region 144 can be formed in the process of forming the connection hole 200a while reducing the mask process for removing the sidewall. Accordingly, the number of processes for manufacturing the semiconductor device is not increased, and the P/N bonding leakage does not occur.

Moreover, in the fourth embodiment, after forming the base layer 152 and the sidewall body 154, the sidewall 150 may be etched back at least in the region where the gate interconnect 140 and the contact (plug) 200 are connected to each other before forming the stopper layer 300, similar to the first or second embodiment.

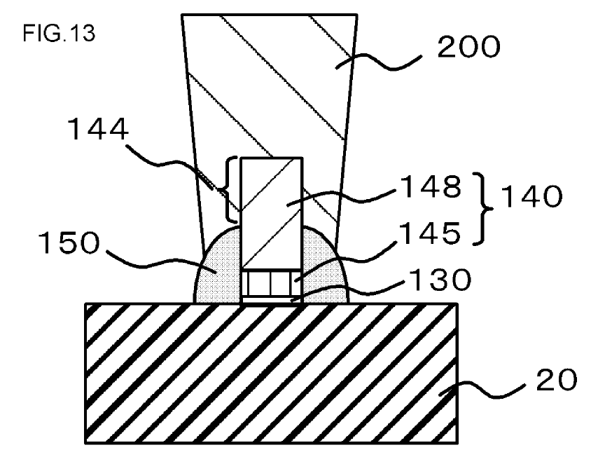

FIG. 11 is a sectional view showing a semiconductor device according to a fifth embodiment. FIG. 11 corresponds to the sectional view taken along the line B-B′of FIG. 2 in the first embodiment. This semiconductor device is the same as the semiconductor device according to the first embodiment except that approximately the entire gate interconnect 140 is formed by the silicide layer 142. A method of manufacturing the semiconductor device according to the fifth embodiment is the same as that in the first embodiment. Also in the fifth embodiment, the same effects as in the first embodiment can be achieved.

FIG. 12 is a sectional view showing a semiconductor device according to a sixth embodiment. FIG. 12 corresponds to the sectional view taken along the line B-B′ of FIG. 2 in the first embodiment. This semiconductor device is the same as the semiconductor device according to the first embodiment except that the gate interconnect 140 has a structure where a metal layer 145 for work function control, a polysilicon layer 146, and a silicide layer 142 are laminated in this order. A method of manufacturing the semiconductor device according to the sixth embodiment is the same as that in the first embodiment that the metal layer 145 and the polysilicon layer 146 are laminated in this order and this laminated layer is selectively removed to thereby except form the gate interconnect 140. The silicide layer 142 is formed by the same process as in the first embodiment. The metal layer 145 for work function control may be formed of La, for example, when a transistor in the element region is an N-channel MOSFET and may be formed of Al, for example, when a transistor in the element region is a P-channel MOSFET. Also in the sixth embodiment, the same effects as in the first embodiment can be achieved since the silicide layer 142 is in contact with the contact (plug) 200 in the region 144.

FIG. 13 is a sectional view showing a semiconductor device according to a seventh embodiment. FIG. 13 corresponds to the sectional view taken along the line B-B′ of FIG. 2 in the first embodiment. This semiconductor device is the same as the semiconductor device according to the first embodiment except that the gate interconnect 140 has a structure where a metal layer 145 for work function control and a low resistance layer 148 are laminated in this order. The low resistance layer 148 is a metal layer, for example. However, the low resistance layer 148 may be a silicide layer.

A method of manufacturing the semiconductor device according to the seventh embodiment is the same as the method of manufacturing the semiconductor device according to the sixth embodiment when the low resistance layer 148 is a silicide layer. Moreover, the method of manufacturing the semiconductor device when the low resistance layer 148 is a metal layer is the same as that in the first embodiment except that the metal layer 145 and the low resistance layer 148 are laminated in this order and this laminated layer is selectively removed to thereby form the gate interconnect 140. Also in the seventh embodiment, the same effects as in the first embodiment can be achieved since the region 144 is the low resistance layer 148 and the low resistance layer 148 is in contact with the contact (plug) 200.

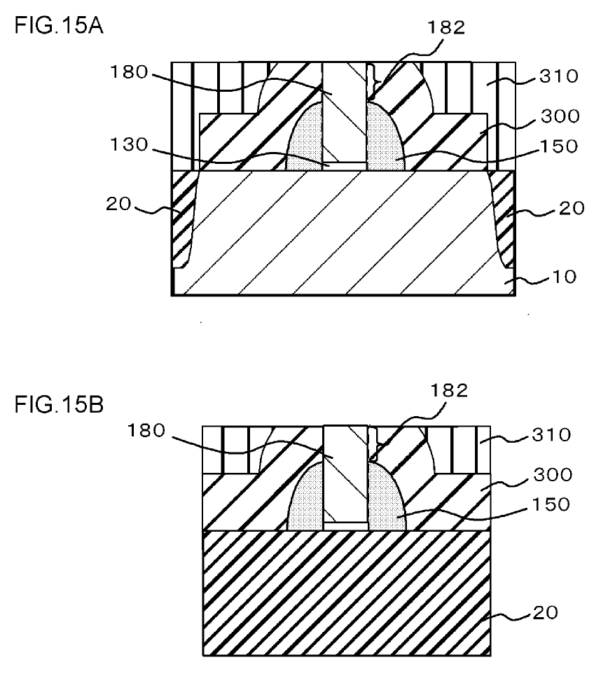

FIG. 14 is a sectional view showing a semiconductor device according to an eighth embodiment. FIG. 14 corresponds to the sectional view taken along the line B-B′ of FIG. 2 in the first embodiment. This semiconductor device is the same as the semiconductor device according to the first embodiment except that the metal layer 145 for work function control is provided at bottom and side surfaces of the gate interconnect 140 and the remaining portion of the gate interconnect 140 is formed by a metal layer 149.

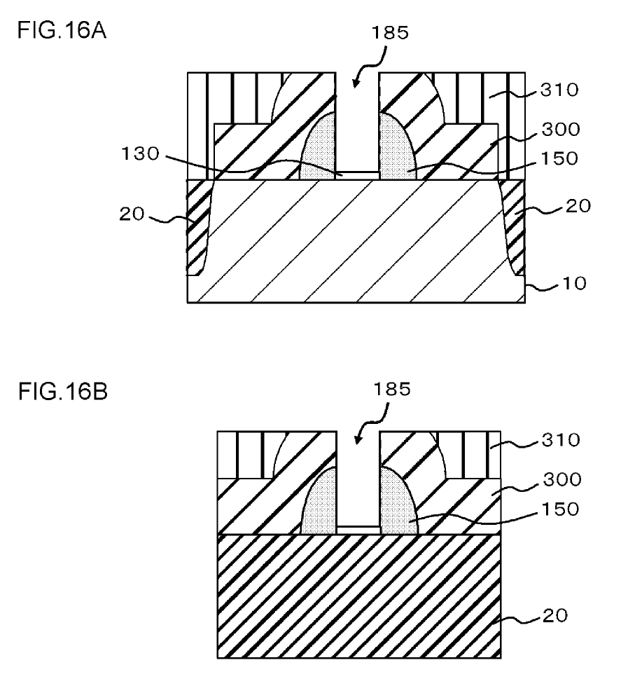

FIGS. 15A to 16B are views showing a method of manufacturing the semiconductor device according to the eighth embodiment. In the drawings, FIGS. 15A and 16A correspond to the sectional view taken along the line A-A′ of FIG. 2 in the first embodiment, and FIGS. 158 and 168 correspond to the sectional view taken along the line B-B′ of FIG. 2 in the first embodiment. First, as shown in FIGS. 15A and 15B, a transistor having a dummy gate interconnect 180 instead of the gate interconnect 140 is formed. Although a material of the dummy gate interconnect 180 is not particularly limited, for example, polysilicon may be used. A method of forming the transistor is the same as the method of forming a transistor in the first embodiment. In this step, a region 182 which is not covered by the sidewall 150 is formed at the side surface of the dummy gate interconnect 180. A method of forming the region 182 is the same as the method of forming the region 144 in the first embodiment.

Then, a stopper layer 300 and an interlayer insulating layer 310 are formed in this order over a transistor of the element region, the dummy gate interconnect 180, and the element isolation layer 20. Then, the interlayer insulating layer 310 and the stopper layer 300 are polished by the chemical mechanical polishing (CMP) method in order to expose an upper surface of the dummy gate interconnect 180.

Then, as shown in FIGS. 16A and 16B, the dummy gate interconnect 180 is removed by etching to thereby form a hole 185.

Then, the metal layer 145 and the metal layer 149 are laminated in this order over the stopper layer 300 and the interlayer insulating layer 310 within the hole 185, and the metal layers 145 and 149 over the stopper layer 300 and the interlayer insulating layer 310 are removed by the CMP method. As a result, the gate interconnect 140 shown in FIG. 14 is formed. In the gate interconnect 140, the region 144 is formed in a portion corresponding to the region 182 in the dummy gate interconnect 180. In addition, the length of the region 144 in the height direction becomes shorter than that of the region 182 because the region 144 is processed by the CMP method. In the region 144, the metal layer 145 is located at the surface. Then, an interlayer insulating layer is formed again and the contacts (plugs) 200 and 210 are embedded in the interlayer insulating layer.

Also in the eighth embodiment, the same effects as in the first embodiment can be achieved since the metal layer 145 is located at the surface in the region 144.

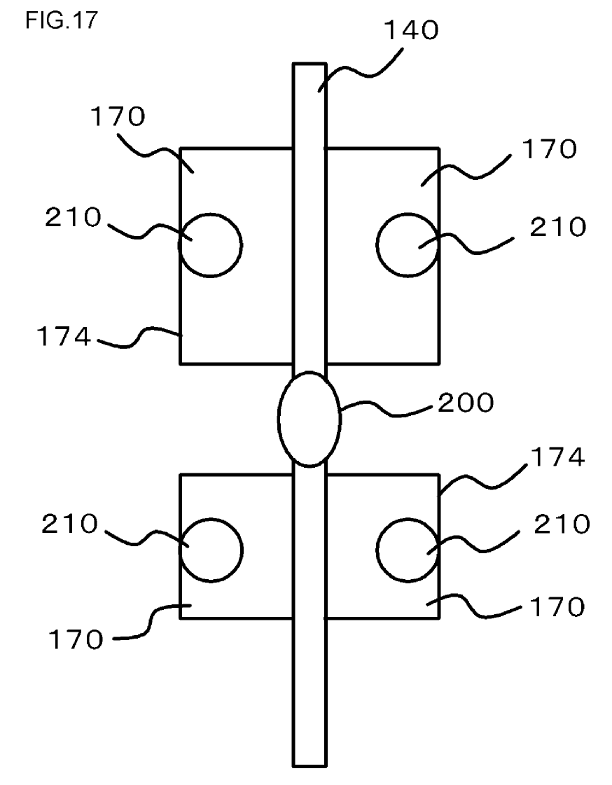

FIG. 17 is a plan view showing a semiconductor device according to a ninth embodiment. FIG. 17 is a view corresponding to FIG. 2 in the first embodiment. This semiconductor device is the same as those according to the first to eighth embodiments except that the sectional shape of the contact (plug) 200 is elliptical and the long axis of the ellipse is inclined with respect to the width direction of the gate interconnect 140. In addition, a method of manufacturing the semiconductor device according to the ninth embodiment is approximately the same as the method of manufacturing the semiconductor device according to any one of the first to eighth embodiments. It is preferable that the long axis of the contact (plug) 200 is parallel to the extending direction of the gate interconnect.

According to the ninth embodiment, the same effects as in the first to eighth embodiments can be achieved. In addition, since the long axis of the contact (plug) 200 is inclined with respect to the width direction of the gate interconnect 140, the contact area between the contact (plug) 200 and the region 144 provided at the side surface of the gate interconnect 140 becomes large. Accordingly, the connection resistance between the contact 200 and the gate interconnect 140 can be reduced further.

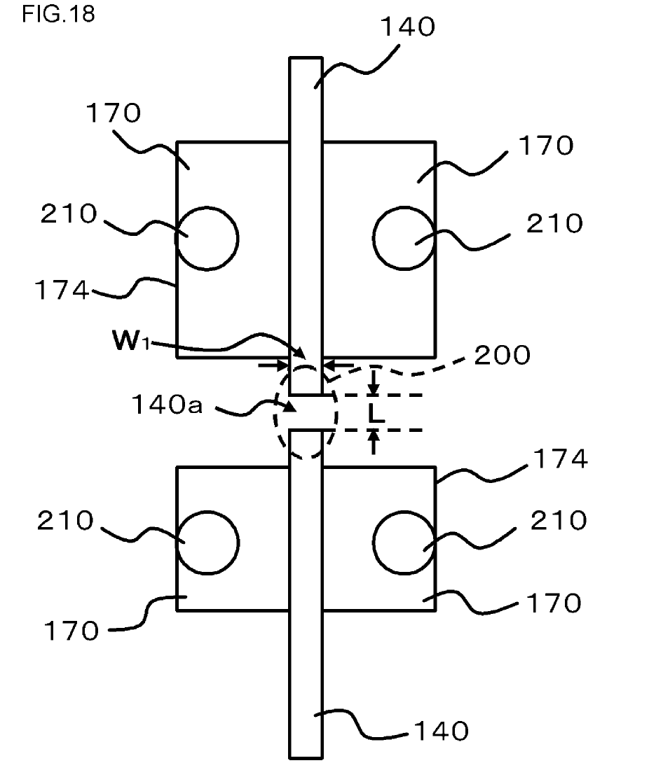

FIG. 18 is a plan view showing a semiconductor device according to a tenth embodiment. FIG. 18 is a view corresponding to FIG. 2 in the first embodiment. This semiconductor device is the same as the semiconductor device according to the ninth embodiment except that the gate interconnect 140 is divided in a portion connected with the contact (plug) 200 and a divided portion 140a of the gate interconnect 140 is embedded by the contact (plug) 200. The length L of the divided portion 140a of the gate interconnect 140 is smaller than the width W1 of the gate interconnect 140. The region 144 is also formed in the end surface of the divided portion 140a of the gate interconnect 140. The gate interconnect 140 is in contact with the contact (plug) 200 in each region 144 of the upper surface, side surface, and end surface. A method of manufacturing the semiconductor device according to the tenth embodiment is the same as that in the ninth embodiment. Moreover, in FIG. 18, the contact (plug) 200 is shown by a dotted line for explanation.

Also in the tenth embodiment, the same effects as in the ninth embodiment can be achieved. In addition, since the division length L of the gate interconnect 140 is smaller than the width W of the gate interconnect 140, the contact area between the gate interconnect 140 and the contact (plug) 200 becomes large compared with the case where the gate interconnect 140 is not divided. Accordingly, the connection resistance between the contact (plug) 200 and the gate interconnect 140 can be reduced further.

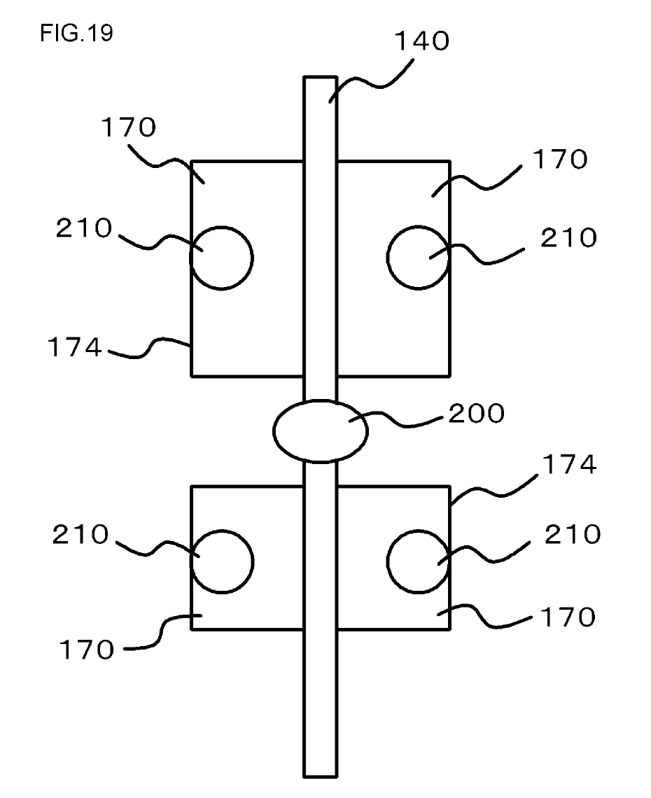

FIG. 19 is a plan view showing a semiconductor device according to an eleventh embodiment. FIG. 19 is a view corresponding to FIG. 2 in the first embodiment. This semiconductor device is the same as that according to the ninth embodiment except from that the long axis of the contact (plug) 200 is parallel to the width direction of the gate interconnect 140. A method of manufacturing the semiconductor device according to the eleventh embodiment is the same as that in the ninth embodiment.

Also in the eleventh embodiment, the same effects as in the first embodiment can be achieved. In addition, since the long axis of the contact (plug) 200 is parallel to the width direction of the gate interconnect 140, an increase in connection resistance between the contact (plug) 200 and the gate interconnect 140 can be suppressed even when the position of the contact (plug) 200 deviates in the width direction of the gate interconnect 140.

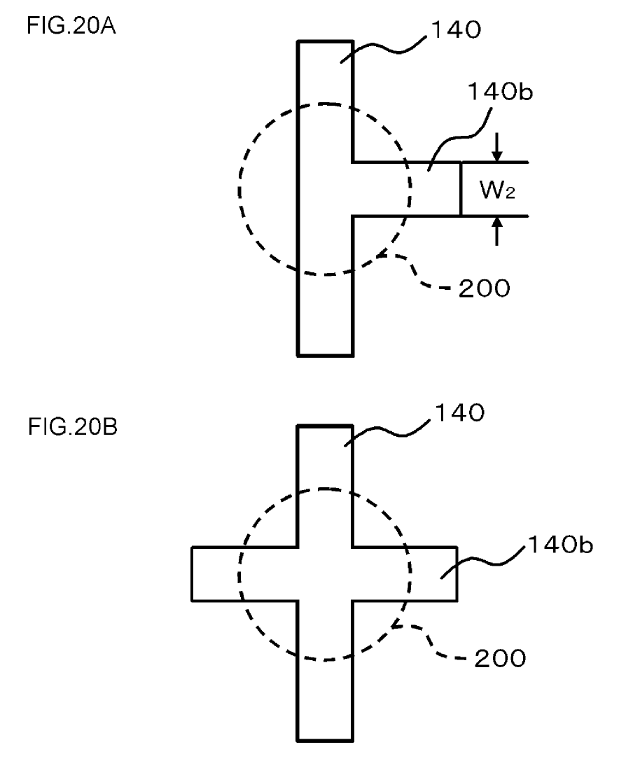

FIGS. 20A and 20B are plan views showing the main parts of a semiconductor device according to a twelfth embodiment. The semiconductor device according to the twelfth embodiment is the same as those according to the first to eleventh embodiments except that the gate interconnect 140 has an auxiliary pattern 140b in a portion connected to the contact (plug) 200. The auxiliary pattern 140b extends in a direction crossing the main body of the gate interconnect 140. The width W2 of the auxiliary pattern 140b is narrower than the diameter of the contact (plug) 200. The configuration of the auxiliary pattern 140b is the same as that of the gate interconnect 140, and has the region 144 at the side surface. Moreover, in FIGS. 20A and 20B, the contact (plug) 200 is shown by a dotted line for explanation.

The auxiliary pattern 140b may extend from one side surface of the main body of the gate interconnect 140 as shown in FIG. 20A or may extend from each of two side surfaces of the main body of the gate interconnect 140 as shown in FIG. 20B. For example, the auxiliary pattern 140b extends in a direction perpendicular to the gate interconnect 140. A method of manufacturing the semiconductor device according to the twelfth embodiment is the same as the method of manufacturing the semiconductor device according to any one of the first to eleventh embodiments except that the auxiliary pattern 140b is formed when forming the main body of the gate interconnect 140.

Also in the twelfth embodiment, the same effects as in the first to eleventh embodiments can be achieved. In addition, since the region 144 of the auxiliary pattern 140b is in contact with the contact (plug) 200, the connection resistance between the contact (plug) 200 and the gate interconnect 140 can be reduced further.

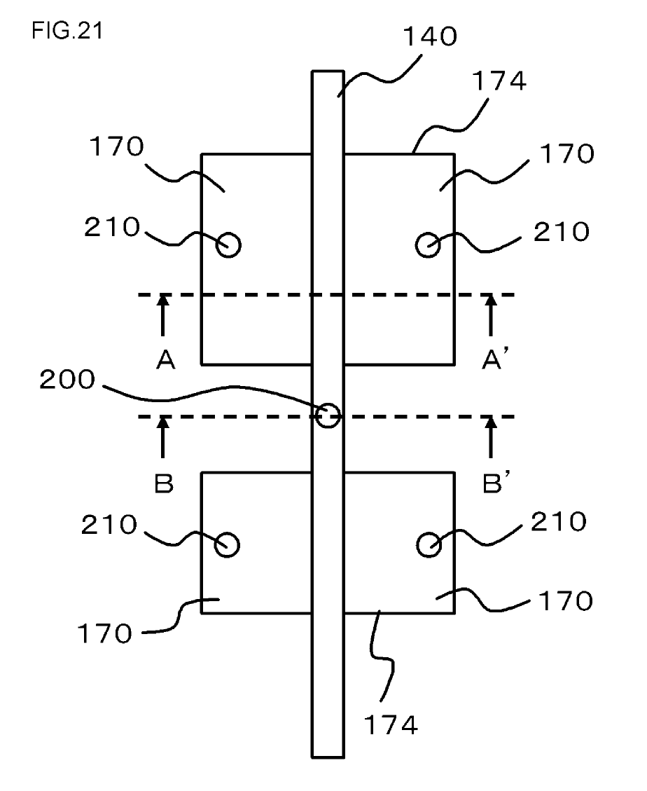

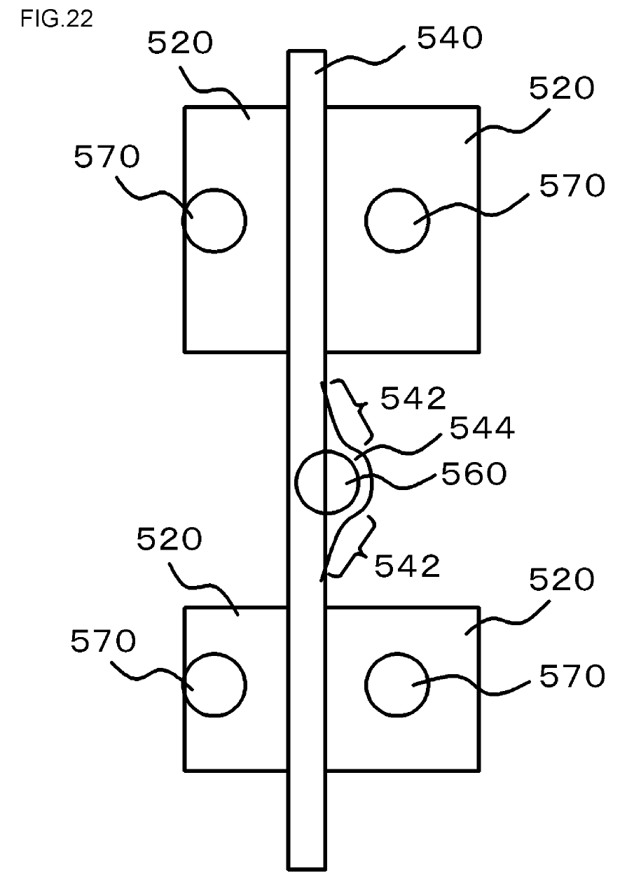

FIG. 21 is a plan view showing the configuration of a semiconductor device according to a thirteenth embodiment. FIG. 21 corresponds to FIG. 2 in the first embodiment and is the same as the first embodiment except that the diameters of the contacts (plugs) 200 and 210 are equal to or less than the width of the gate interconnect 140. Hereinafter, the same components as in the first embodiment are denoted by the reference numerals, and the explanation will not be repeated.

When the contact (plug) 200 protrudes from the gate interconnect 140, the region 144 of the gate interconnect 140 and the contact (plug) 200 are in contact with each other. Accordingly, an increase in connection resistance between the contact (plug) 200 and the gate interconnect 140 can be suppressed. Thus, also in the thirteenth embodiment, even if the positional deviation of the contact occurs, it is suppressed that the connection resistance becomes larger than the reference value. As a result, an influence of the positional deviation of the contact on the circuit characteristics can be reduced.

In addition, if the diameters of the contacts (plugs) 200 and 210 are set to be equal to or less than the width of the gate interconnect 140 like the thirteenth embodiment in the semiconductor devices according to the second to seventh and ninth to twelfth embodiments, the same effects as in the thirteenth embodiment can be acquired.

While the first to thirteenth embodiments of the present invention have been described with reference to the drawings, these are only illustration of the present invention, and other various configurations may also be adopted.

For example, in the methods of manufacturing the semiconductor devices according to the first to seventh and ninth to thirteenth embodiments, the process of forming the region 144 by forming the sidewall 150 low may be performed after the process of forming the impurity diffusion layer 170.

Moreover, in this case, after forming the impurity diffusion layer 170, the process of forming the suicide block film described using FIGS. 1A and 1B may be performed before the process of forming the region 144. In this case, after the silicide block film is formed, the region 144 is formed and then the silicide layers 142 and 172 are formed.

Moreover, in the methods of manufacturing the semiconductor devices according to the first to seventh and ninth to thirteenth embodiments, the process of forming the region 144 by forming the sidewall 150 to be low may be performed after the process of forming the suicide layers 142 and 172.

In addition, the following invention is also disclosed in the above embodiments. That is, there is disclosed a semiconductor device including: an element isolation layer provided in a semiconductor layer; an element region divided by the element isolation layer; a gate interconnect which extends linearly over the element region and the element isolation layer; and a contact (plug) which is connected to the gate interconnect located over the element isolation layer and of which the diameter of a section is larger than the width of the gate interconnect.

It is apparent that the present invention is not limited to the above embodiment, but may be modified and changed without departing from the scope and spirit of the invention.

What is claimed is:

1. A semiconductor device comprising:
a substrate;
an element isolation layer provided on said substrate;
an element region divided by said element isolation layer;
a gate interconnect including a sidewall and extending over said element region and said element isolation layer;
an insulating layer on said substrate; and
a contact connected to said gate interconnect with an upper and a side surface of said gate interconnect located over said element isolation layer through said insulating layer,
wherein a film thickness of said sidewall on said element isolation layer on said substrate is substantially equal to a film thickness of said sidewall on said element region.

2. The semiconductor device according to claim 1,
wherein said insulating layer includes an etch stop film.

3. The semiconductor device according to claim 2,
wherein said sidewall includes a film made of a material which is the same material as said etch stop film.

4. The semiconductor device according to claim 1,
wherein said sidewall is located at a position which is below by equal to or more ⅕ of the gate height from an upper surface of said gate interconnect.

5. The semiconductor device according to claim 1,
wherein said sidewall is located at a position which is below equal to or more than 10 nm from an upper surface of said gate interconnect.

6. The semiconductor device according to claim 1,
wherein said gate interconnect includes a silicide layer in at least a part and an upper surface of said region.

7. The semiconductor device according to claim 1,
wherein said gate interconnect is formed of metal in said region.

8. The semiconductor device according to claim 1,
wherein in said gate interconnect, the width of a portion connected with said contact is equal to the width of a portion located over said element region.

9. The semiconductor device according to claim 1,
wherein the sectional shape of said contact is elliptical, and the long axis of the ellipse is inclined with respect to the width direction of said gate interconnect.

10. The semiconductor device according to claim 1,
wherein the diameter of said contact is larger than the width of said gate interconnect.

11. The semiconductor device according to claim 8,
wherein said gate interconnect is divided in a portion connected to said contact, and the division length is smaller than the width of said gate interconnect, and
a divided portion of said gate interconnect is embedded by said contact.

12. The semiconductor device according to claim 1,
wherein the height of said sidewall in a portion where said gate interconnect is connected to said contact is lower than the height of said sidewall located over said element region.

13. The semiconductor device according to claim 1,
wherein the height of said sidewall in a portion where said gate interconnect is connected to said contact is equal to the height of said sidewall located over said element region.

14. The semiconductor device according to claim 1,
wherein said gate interconnect includes an auxiliary pattern, which extends in a direction crossing said gate interconnect, in a portion connected to said contact, and
the width of said auxiliary pattern is narrower than the diameter of said contact.
